(19) United States
(12) Patent Application Publication
(10) Pub. No.: US 2014/0077660 A1
(43) Pub. Date: Mar. 20, 2014

(54) SMART MATERIAL ACTUATOR

(71) Applicant: PARKER-HANNIFIN CORPORATION, Cleveland, OH (US)

(72) Inventor: Steven R. Knight, Killingworth, CT (US)

(21) Appl. No.: 14/119,036

(22) PCT Filed: May 25, 2012
(86) PCT No.: PCT/US12/39567

§ 371 Date: Nov. 20, 2013

Related U.S. Application Data
(60) Provisional application No. 61/489,789, filed on May 25, 2011.

(51) Int. Cl. H01L 41/09

(52) U.S. Cl. CPC H01L 41/09
USPC 310/328

(57) ABSTRACT

A smart material actuator including a smart material stack and a compensator preventing expansion of the stack in a non-driving direction. When actuated, the smart material stack causes a force transfer surface to be driven in the driving direction, thereby actuating a first stage amplifier having two arms, which in turn actuates a second stage amplifier having two arms.

### RELATED APPLICATION

This application claims priority of U.S. Provisional Application No. 61/489,789 filed May 25, 2011, the entirety of which is incorporated herein by reference.

### BACKGROUND

The present invention relates generally to actuators, and particularly to actuators employing smart material, such as piezoelectric material.

Actuators drive motion in mechanical systems, typically by converting electrical energy into mechanical motion. Some actuators cause motion with smart materials. For example, electrical energy can be supplied to or removed from a stack of piezoelectric material to cause an expansion/contraction of the material.

The invention is based on actuator technologies being developed for a wide range of applications including industry. One component used in this type of actuator is an electrically stimulated smart material actuator. These smart material actuators when electrically stimulated change shape. This shape change can be designed such that one axis predominantly changes. As this axis changes dimension it is magnified by a lever integral to the main support structure creating an actuator with a useful amount of displacement. This displacement is useful for general-purpose industrial applications such as grippers, linear motors, and consumer applications such as speakers. Presently, electromechanical devices are used such as motors, solenoids, and voice coils. In general these devices encompass many shortcomings, i.e. they are large and heavy, consume high amounts of power, and do not work in a proportional manner.

Various types of smart material actuators are known to those skilled in the art, such as the actuators described in U.S. Pat. No. 7,564,171 to Moler et al., issued Jul. 21, 2009, which is incorporated by reference herein in its entirety. Traditionally a smart material actuator is used two ways, first direct acting and second in a mechanically leveraged system. The present invention is directed to improved actuator designs.

### SUMMARY

The present invention is directed to improved smart material actuators. The smart material actuators include a smart material stack and a compensator preventing expansion of the stack in a non-driving direction. When actuated, the smart material causes a force transfer surface to be driven in the driving direction, thereby actuating a first stage amplifier having two arms, which in turn actuates a second stage amplifier having two arms.

An aspect of the present invention includes a smart material actuator including a smart material stack having a fixed end and a driving end; a compensator at least partially surrounding the smart material stack and providing a fixed surface adjacent the fixed end of the smart material stack; a force transfer surface adjacent the driving end of the smart material stack, wherein the force transfer surface is driven by the driving end of the smart material stack; and an amplifier. The amplifier may include two first stage arms having an actuator end and being actuated by movement of the force transfer surface, and two second stage arms having an actuator end and being actuated by movement of the actuator end of the first stage arms. The movement of the actuator end of the first stage arms may cause the actuator end of the second stage arms to move a greater distance than the force transfer surface is driven by the driving end of the smart material stack.

According to another aspect, the smart material actuator may further include an actuator surface driven by the actuator ends of the second stage arms, wherein the movement of the actuator surface is greater than the movement of the force transfer surface when driven by the driving end of the smart material stack. In addition, the actuator surface and the force transfer surface may move in an axial direction.

According to another aspect, movement of the force transfer surface may cause the actuator surface to move a direction generally opposite that of the movement of the force transfer surface.

According to another aspect, the smart material actuator may further include a housing surrounding the smart material stack and the compensator.

According to another aspect, the smart material stack is at least one of: over-molded; encapsulated; or located within a housing. In addition, the smart material actuator may include an o-ring seal in contact with the housing to limit environmental exposure of the smart material stack. Also, movement of the housing as a result of actuation of the smart material stack may cause rolling of the o-ring seal.

According to another aspect, the first stage arms extend outwardly from the smart material stack in a first direction and the compensator extends outwardly from the smart material stack in a direction offset from the first stage arms by approximately 90 degrees.

According to another aspect, the smart material actuator may further include at least one link connecting the compensator to each of the two first stage arms. In addition, the at least one link may be formed from spring steel.

According to another aspect, the force transfer surface is part of a force transfer member which may actuate the two first stage arms via interaction with a single link between the first stage arms.

According to another aspect, the two first stage arms may be folded spring arms.

According to another aspect, at least one of the force transfer member, the two first stage arms or the compensator may be metal injection molded.

According to another aspect, at least one of the force transfer member, the two first stage arms, or the two second stage arms may be formed from spring steel.

According to another aspect, the compensator and the two first stage arms may be formed by different manufacturing processes.

According to another aspect, the two first stage arms may be part of a single integrally formed spring or the two second stage arms form part of a single integrally formed spring.

According to another aspect, the two second stage arms may be part of a bow-shaped member connecting the actuator end of one of the first stage arms to the actuator end of the other of the first stage arms.

According to another aspect, the two first stage arms may be part of a split can amplifier wherein movement of the force transfer surface causes the two first stage arms to move radially outward.

According to another aspect, the smart material actuator may further include a preload mechanism adapted to apply force to the force transfer surface in a direction opposite the direction in which the force transfer surface is driven by the driving end of the smart material stack.

Another aspect of the present invention includes a smart material actuator including a smart material stack having a fixed end and a driving end; a generally U-shaped compensator at least partially surrounding the smart material stack and providing a fixed surface adjacent the fixed end of the smart material stack; a force transfer member having a force transfer surface adjacent the driving end of the smart material stack, wherein the force transfer surface is driven by the driving end of the smart material stack; and two first stage arms having a actuator end and being actuated by movement of the force transfer member, wherein the two first stage arms are offset by 90 degrees from the sides of the U-shaped compensator. Actuation of the smart material stack may drive movement of the force transfer member, which may cause the actuator end of the first stage arms to move a greater distance than the force transfer surface is driven by the driving end of the smart material stack.

These and further features of the present invention will be apparent with reference to the following description and attached drawings. In the description and drawings, particular embodiments of the invention have been disclosed in detail as being indicative of some of the ways in which the principles of the invention may be employed, but it is understood that the invention is not limited correspondingly in scope. Rather, the invention includes all changes, modifications and equivalents coming within the spirit and terms of the claims appended hereto.

Features that are described and/or illustrated with respect to one embodiment may be used in the same way or in a similar way in one or more other embodiments and/or in combination with or instead of the features of the other embodiments.

It should be emphasized that the term “comprises/comprising” when used in this specification is taken to specify the presence of stated features, integers, steps or components but does not preclude the presence or addition of one or more other features, integers, steps, components or groups thereof.

### BRIEF DESCRIPTION OF THE DRAWINGS

FIGS. 1A-C are views of an embodiment of a smart material actuator having outwardly extending arms;

FIGS. 2A-D are views of an additional embodiment of a smart material actuator having outwardly extending arms;

FIGS. 3A-B are views of an embodiment of a smart material actuator having folded spring arms;

FIGS. 4A-C are views of an embodiment of a smart material actuator having upwardly extending arms;

FIGS. 5-7 are views of additional embodiments of smart material actuators having upwardly extending arms;

FIGS. 8-10 are views of additional embodiments of smart material actuators having a housing enclosing the smart material;

FIGS. 11-16 are views of additional embodiments of smart material actuators suitable for use in split can configurations;

FIGS. 17-25 are views of additional embodiments of smart material actuators having different configurations of outwardly extending arms;

FIGS. 26-34 are views of additional embodiments of smart material actuators having different configurations of folded spring arms;

FIGS. 35-26 are views of additional embodiments of smart material actuators that are suitable for manufacturing using stamping and/or etching processes; and

FIGS. 37-39 illustrate different types of configurations of connections between parts of smart material actuators.

### DETAILED DESCRIPTION

For illustrative purposes, the precepts of a smart material actuator in accordance with the present invention are described in connection with various embodiments and configurations. It will be appreciated, however, that aspects of the present invention will find application in other actuator configurations.

Throughout this disclosure, reference numerals are used to designate elements in the figures referred to in the text. Analogous elements between different embodiments use reference numerals incremented or decremented by multiples of 100 in order to aid in understanding. Such elements may be functionally similar or equivalent to each other, and may share similar or identical physical geometry, but need not do so. Further, some elements common to two or more figures and described elsewhere in the text may be omitted from another figure and/or description for clarity and brevity, but it is understood that this disclosure contemplates that features from one embodiment may be present in another without being explicitly referred to in the text or shown in a figure.

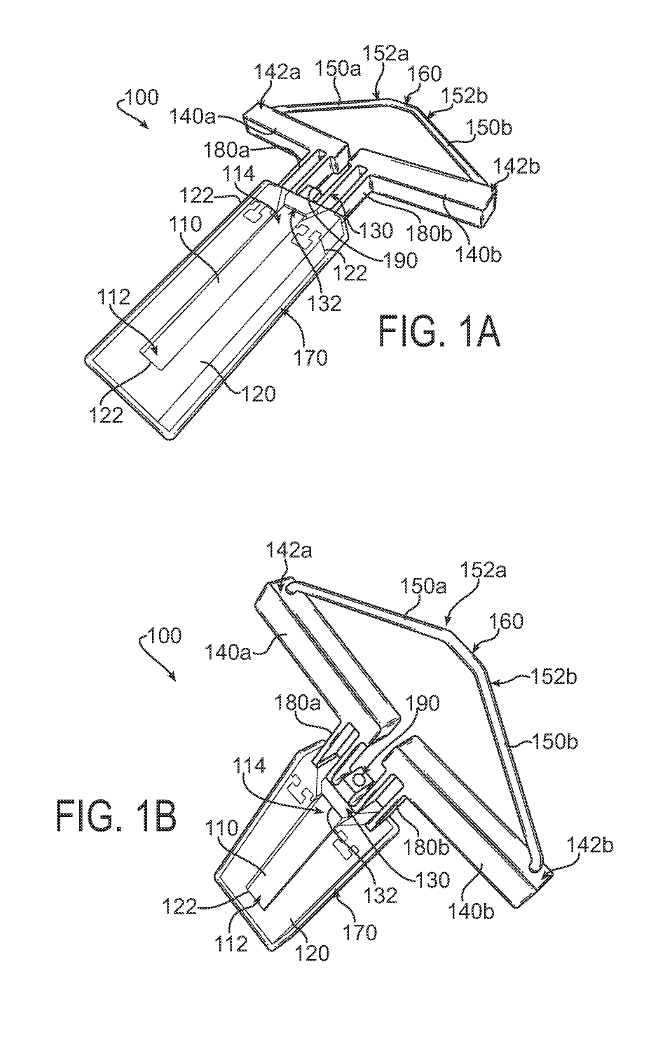

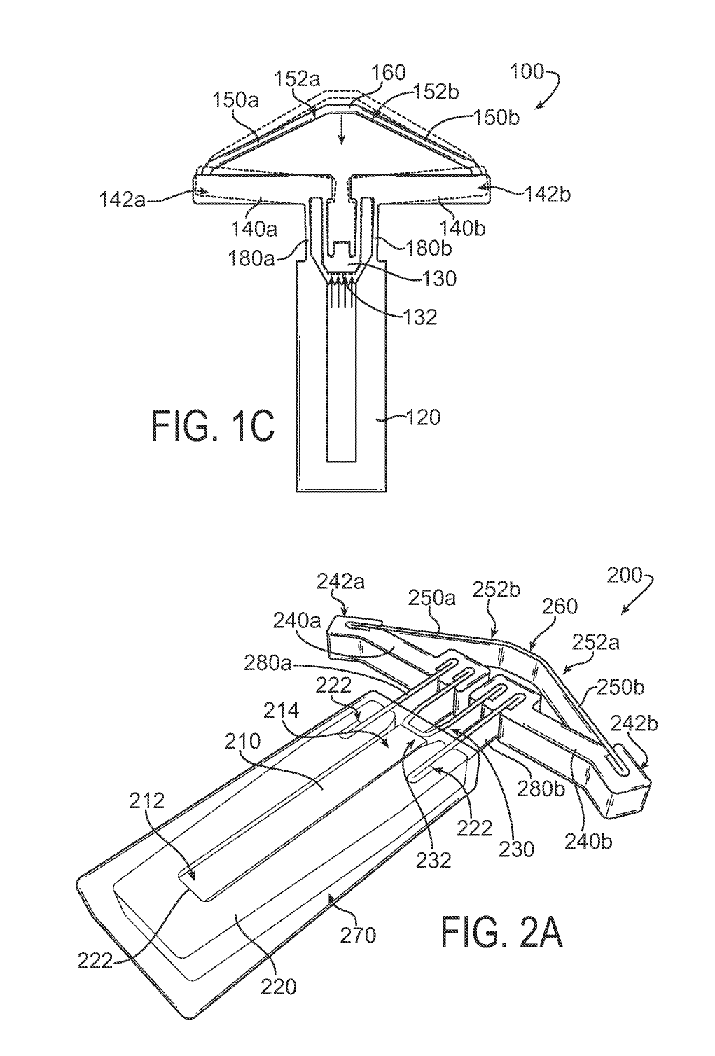

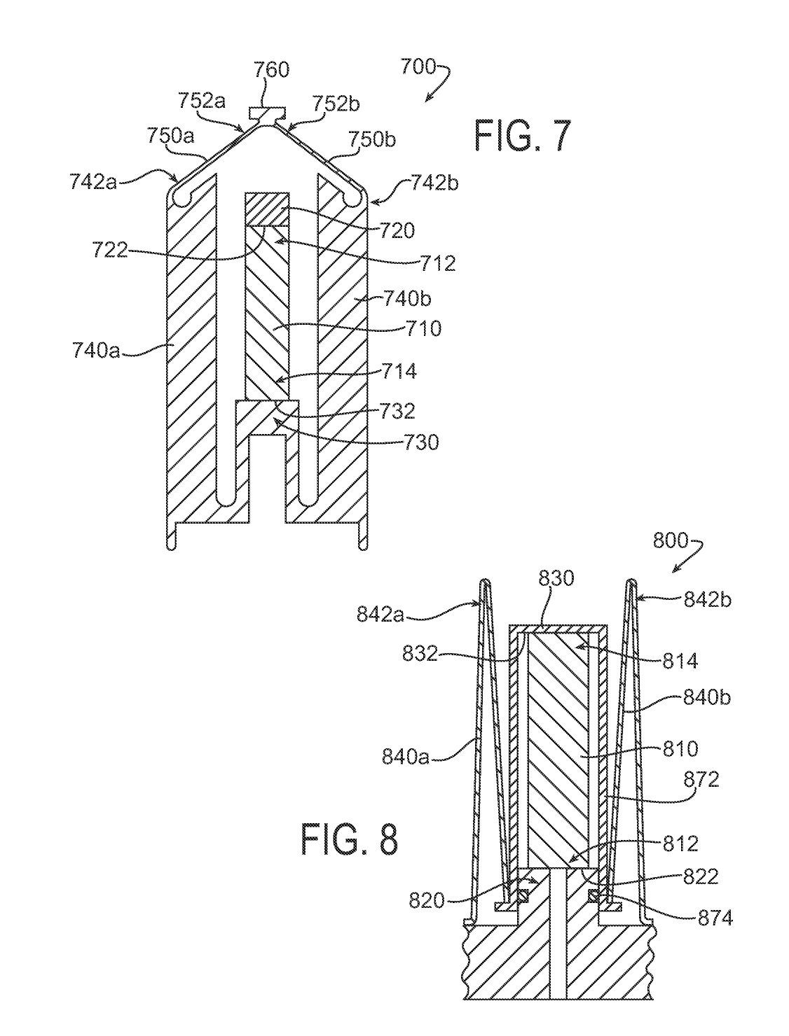

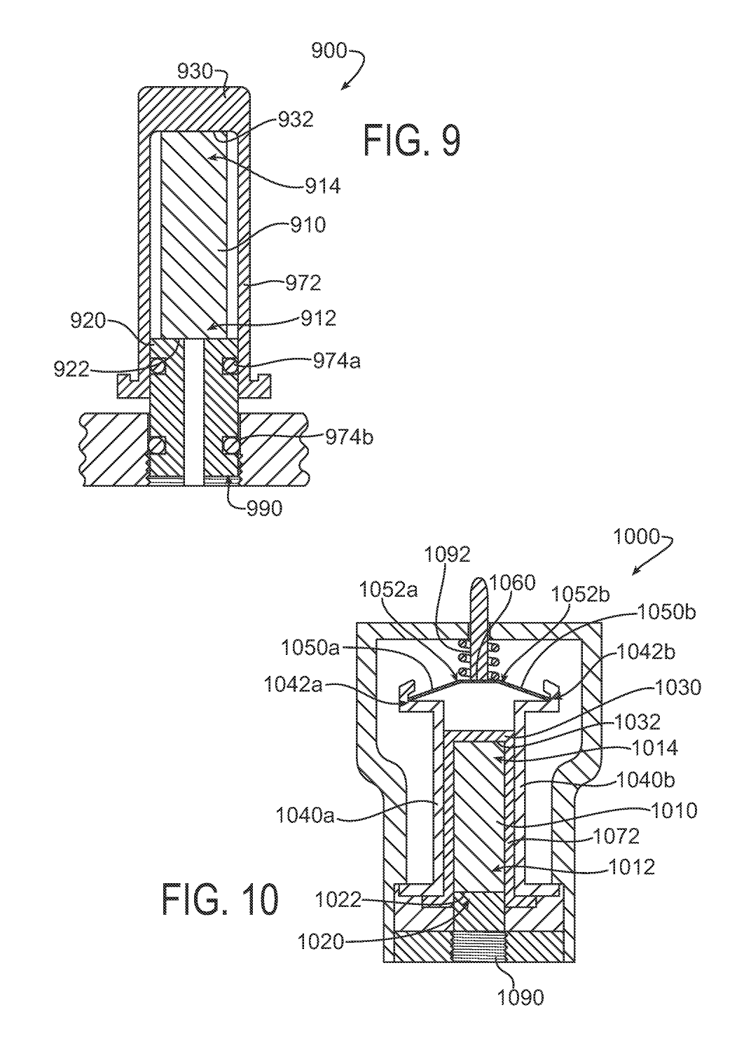

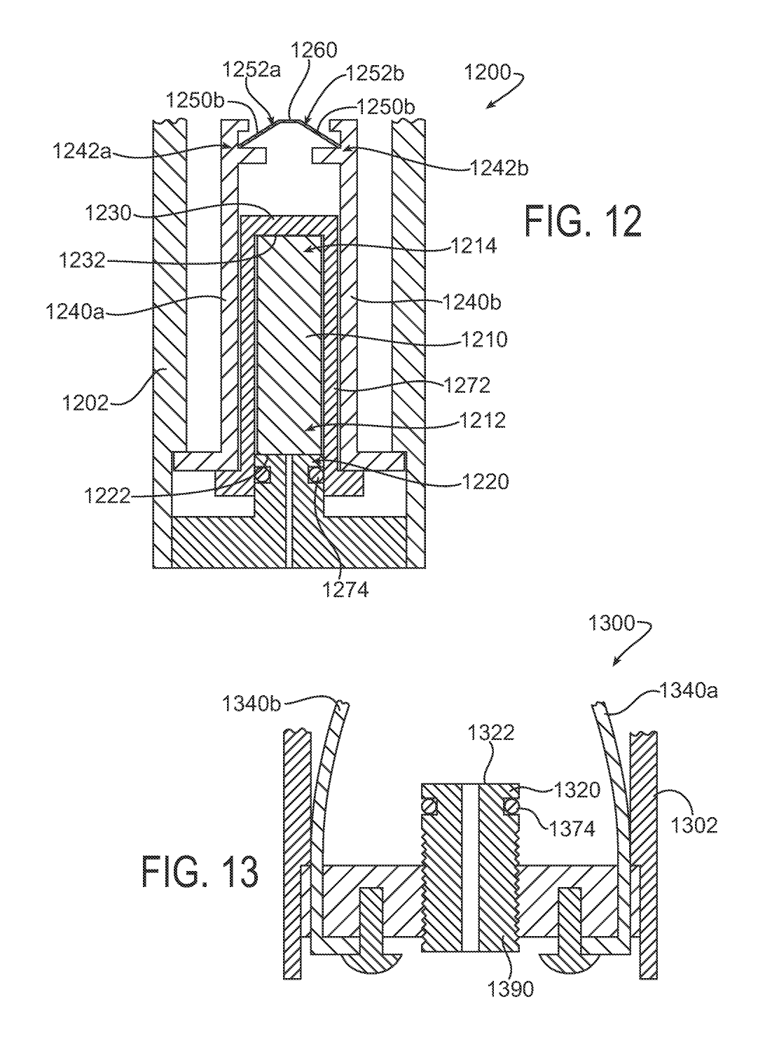

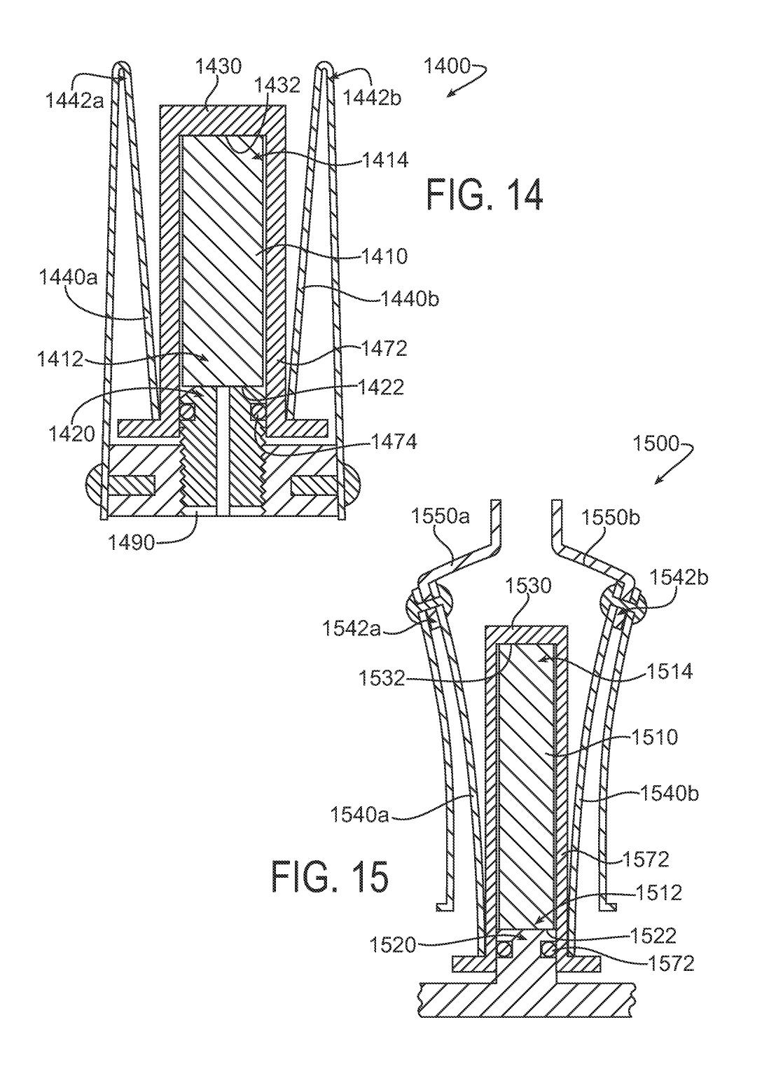

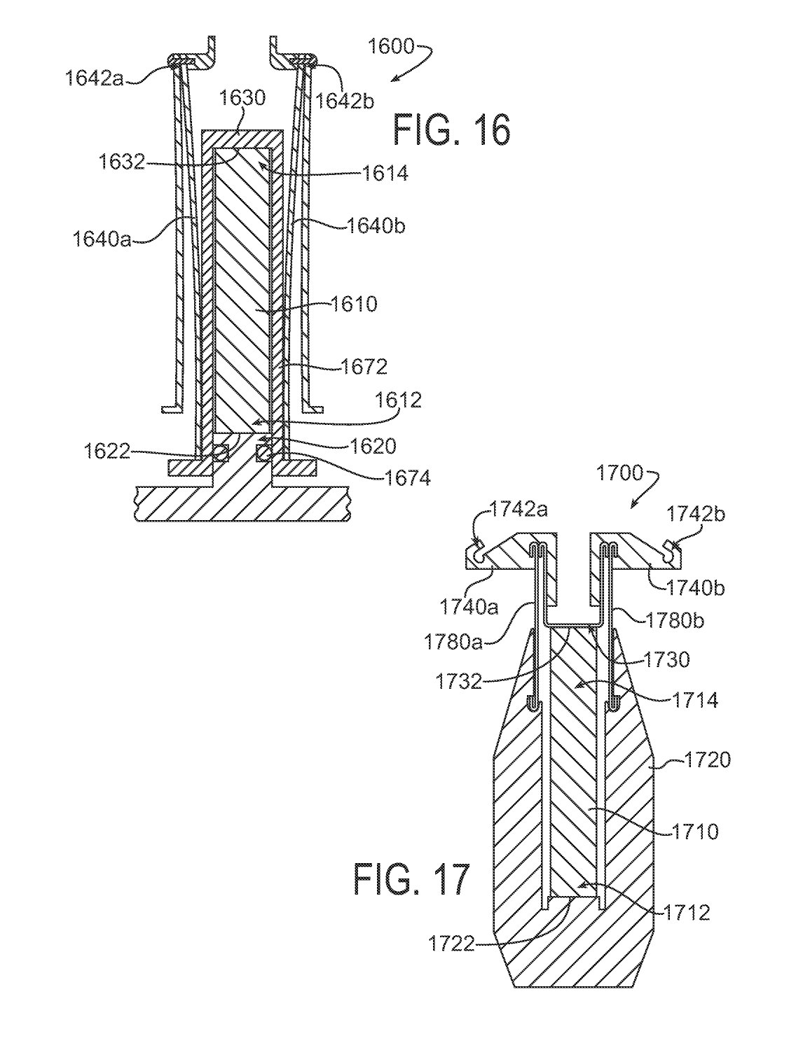

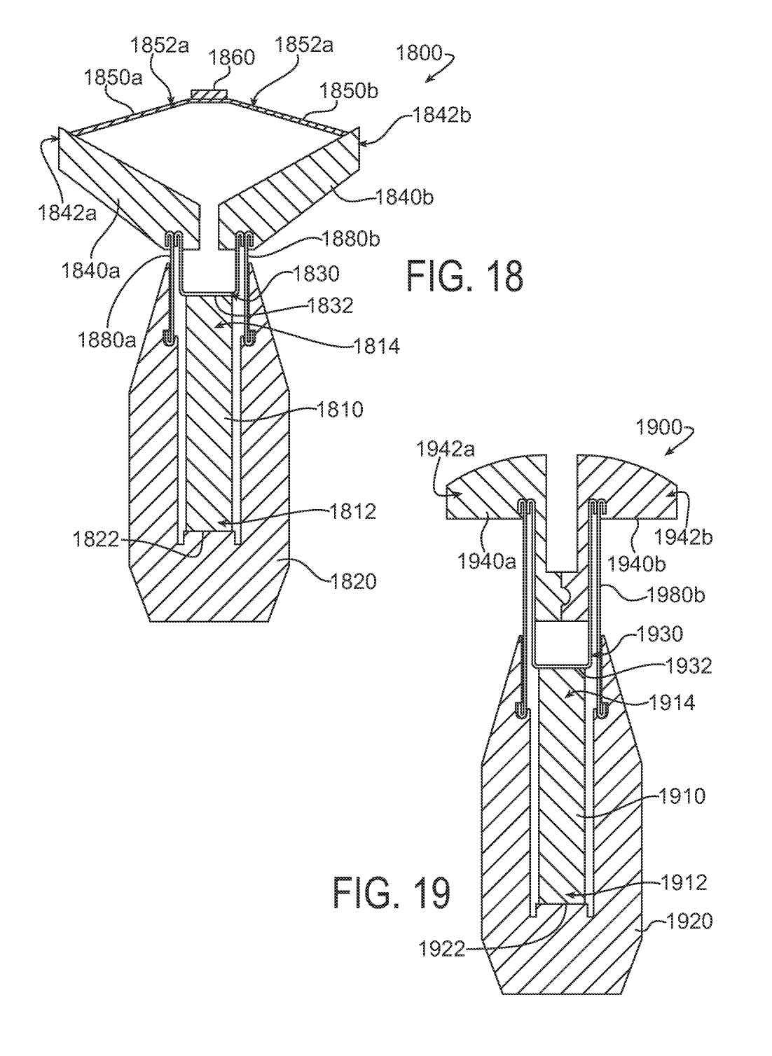

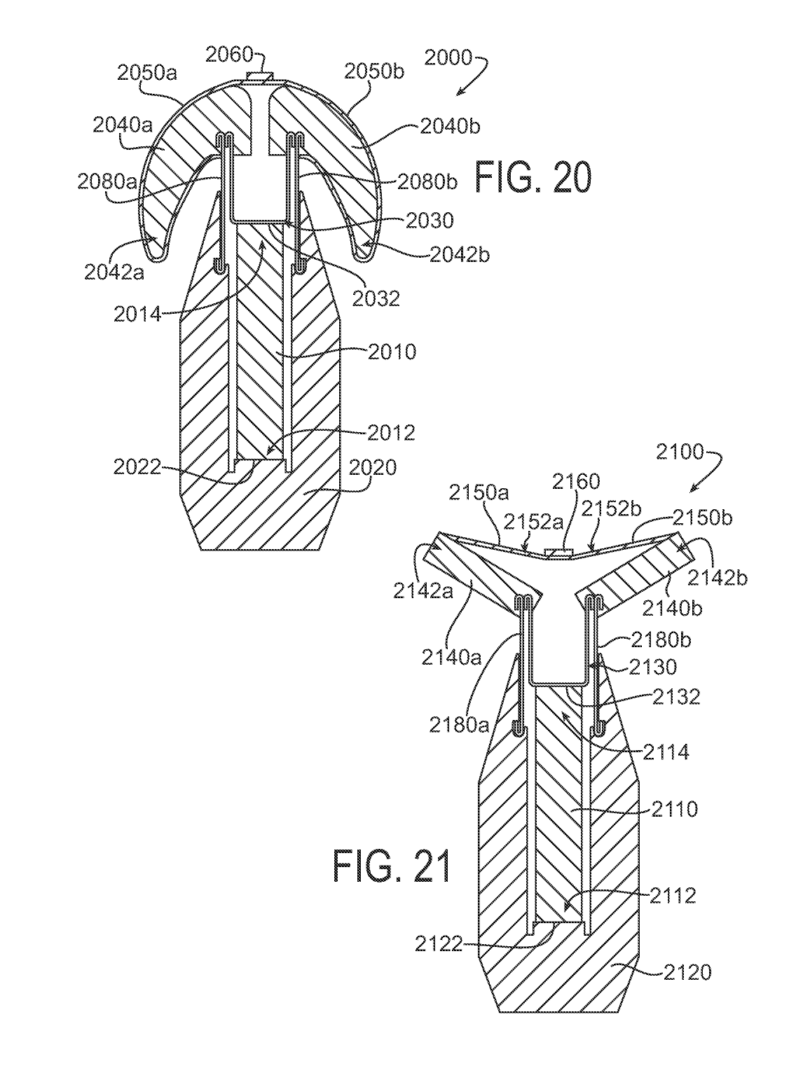

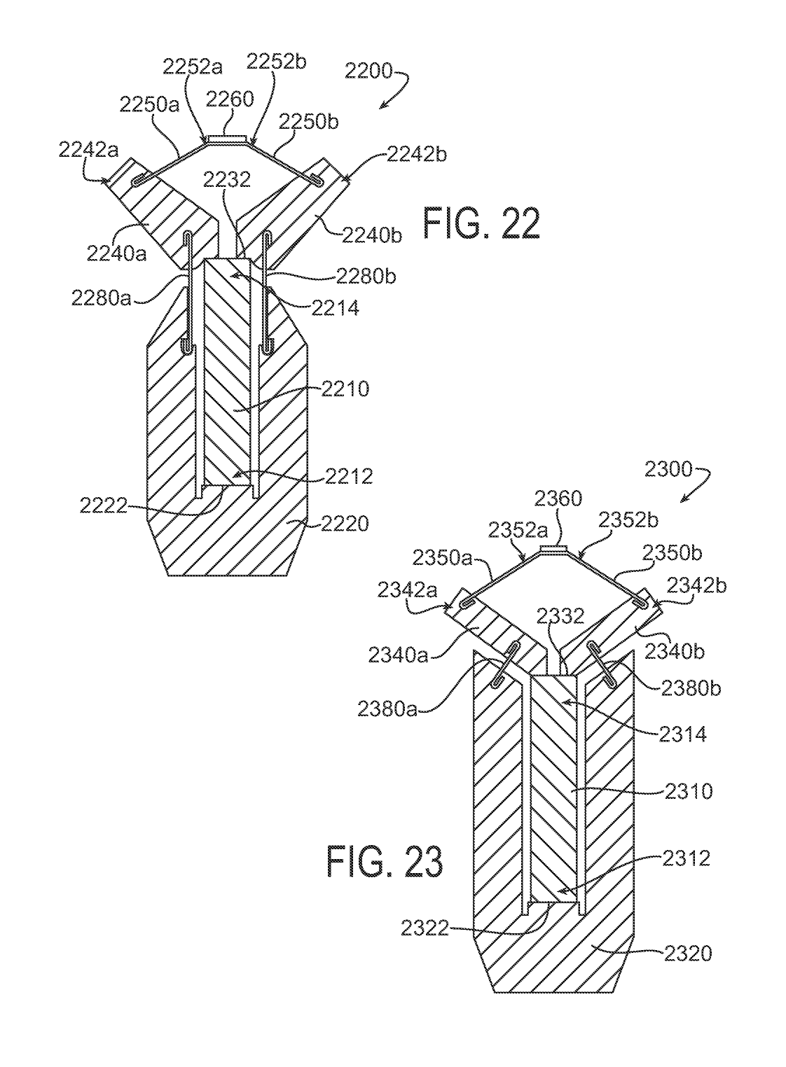

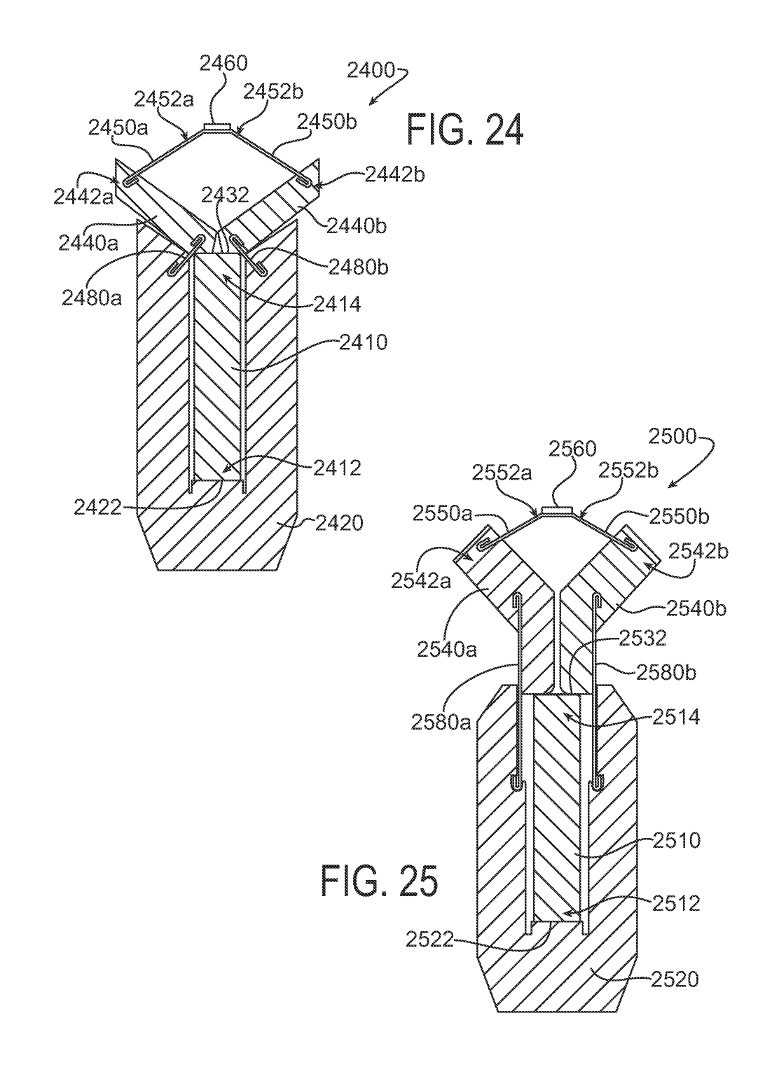

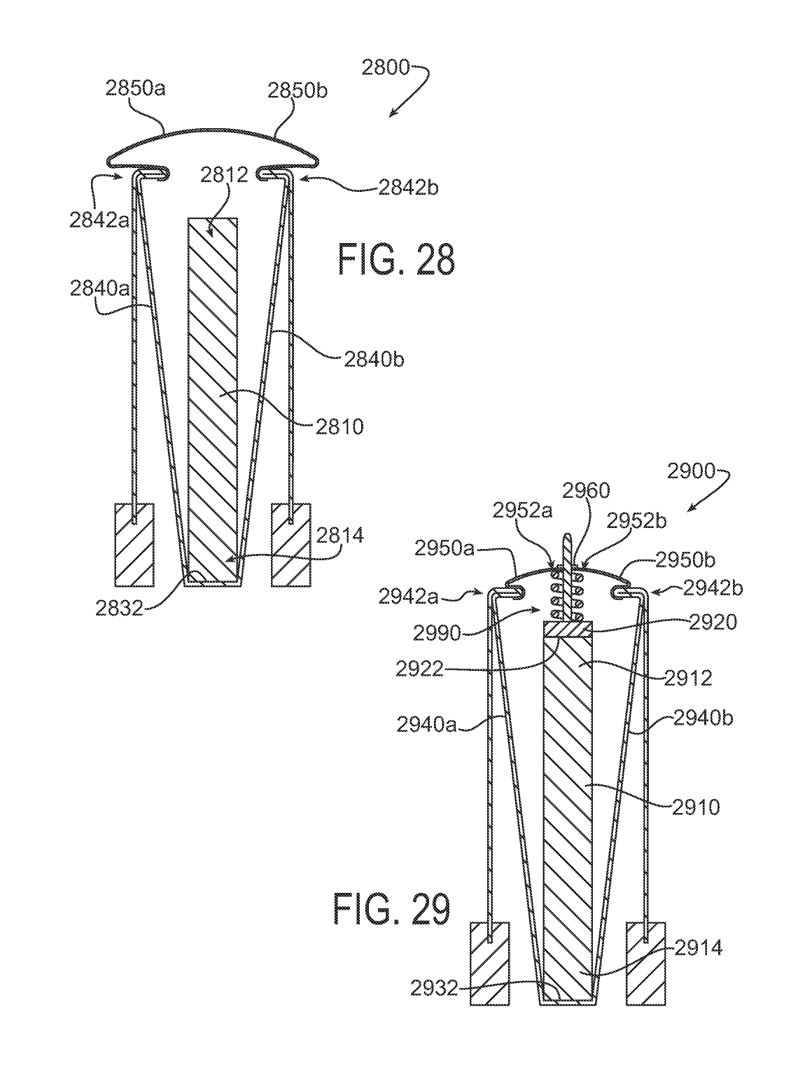

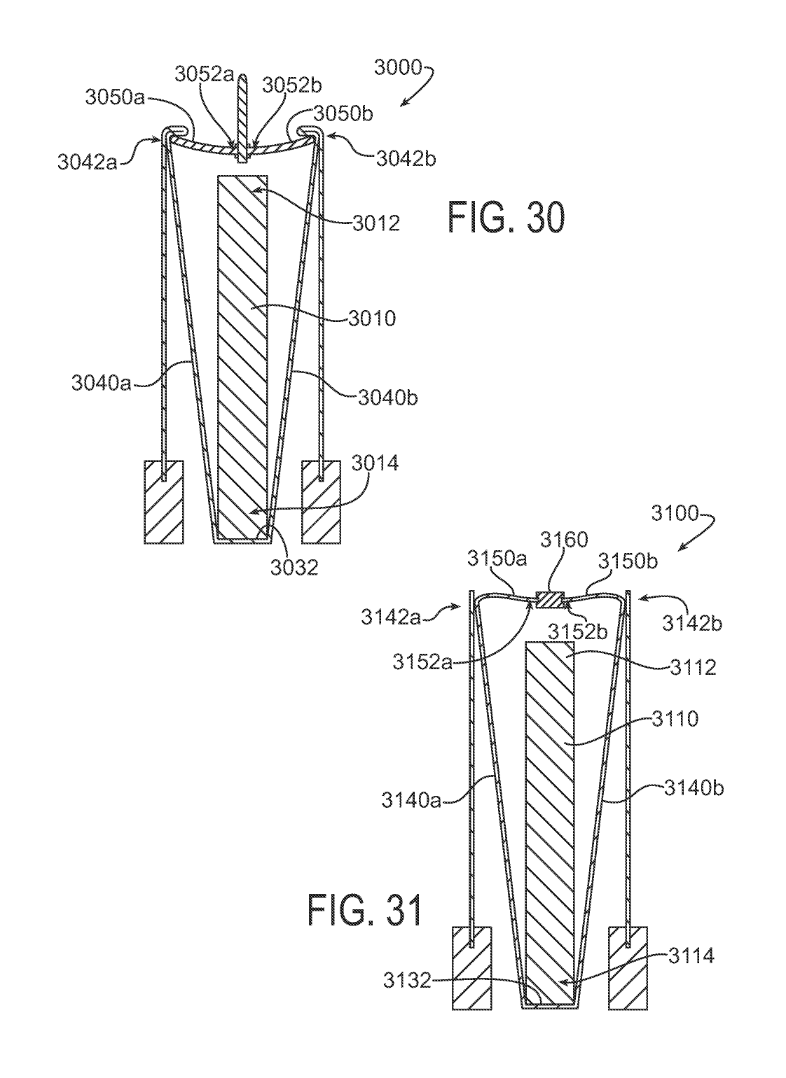

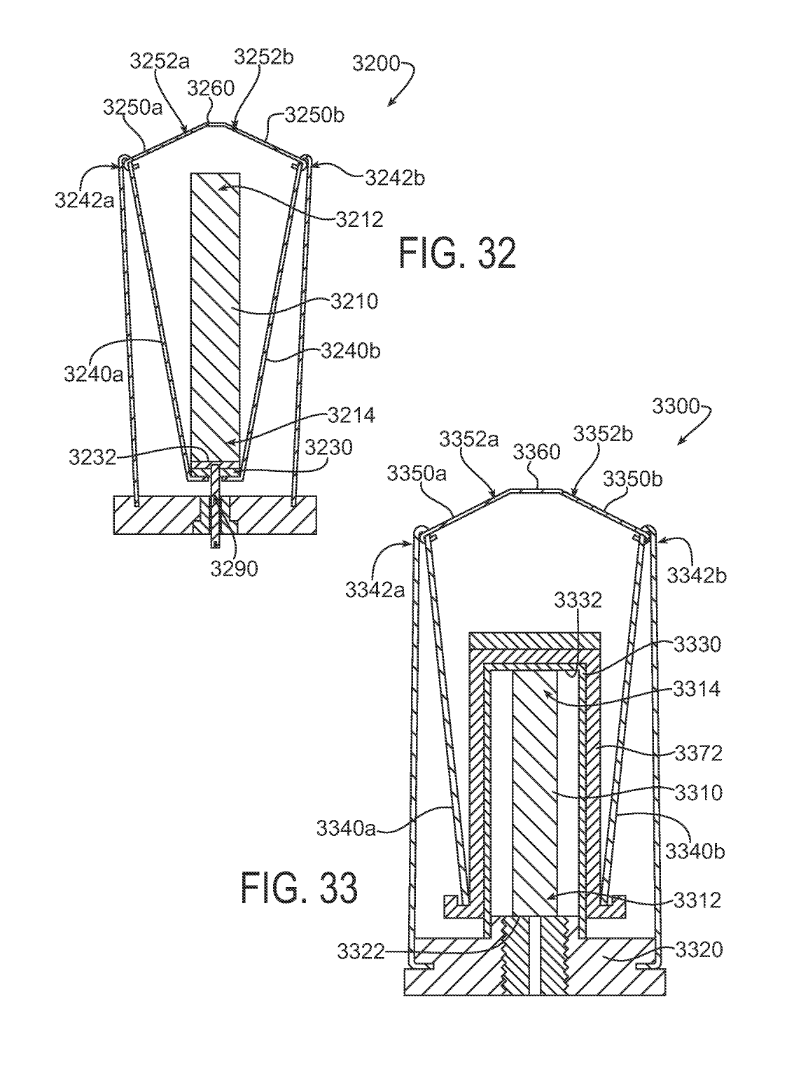

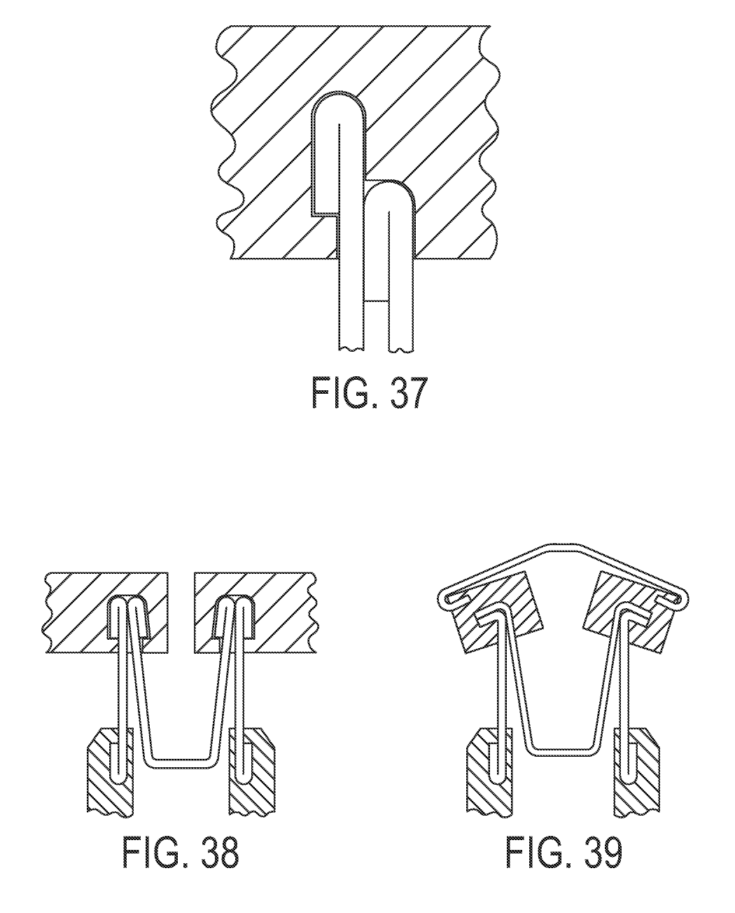

With respect to all embodiments disclosed in FIGS. 1A-39, similar elements across different embodiments are identified by similar numbers. For example, the smart material stack is identified as x10, the compensator is identified as x20, the first stage arms are identified as x40a and x40, etc., where x is the Figure number. Accordingly, one of skill in the art should readily understand the applicability of features of one embodiment as they may be used in conjunction with other embodiments.

Also with respect to all of the embodiments disclosed FIGS. 1A-39, it will be understood that based on the specific designs illustrated in the figures, different materials and manufacturing processes may be suitable for different devices and components thereof, and that combinations of materials and/or processes may be used to manufacture each of the embodiments disclosed.

Turning initially to FIGS. 1A-C, an exemplary actuator is shown. The actuator includes a smart material stack 110, such as a piezoelectric stack that expands and contracts when subject to electrical energy. The stack is at least partially contained within a compensator 120 (which may also be referred to as a “piezo restraint”). The stack 110 has a fixed end 112 and a driving end 114. The compensator 120, which may be generally U-shaped, includes a fixed surface 122 adjacent to, or abutting, the fixed end 112 of the smart material stack 110. Adjacent the driving end 114 of the smart material stack 110 is a force transfer surface 132, which may be located on a force transfer member, such as force transfer member 130.

The force transfer member 130 is connected to first stage arms 140a and 140b, which are part of a first stage amplifier. As used herein, the phrase “connected to” should be understood to include in direction connection with, in indirect connection with, in contact with, or integral with. The first stage arms 140a and 140b each have an actuator end, 142a and 142b, respectively. Exposure of the smart material stack 110 to electrical energy may cause the smart material stack 110 to expand axially, thereby causing the driving end 114 of the smart material stack 110 to move the force transfer surface 132, which in turn causes movement of the actuator ends 142a-b of the first stage arms 140a-b. As shown, the first stage arms 142a-b are connected to the compensator 120, such as by links 180a-b. In addition, the force transfer surface 130 may be located at an interface of the driving end 114 of the smart material stack 110 and a surface of an amplifier element, such as a first stage arm 140a-b. In this manner, the force transfer member 130 could be eliminated from the design.

The first stage arms 140a-b may amplify the movement of the force transfer surface 132 such that the actuator ends 142a-b of the first stage arms 140a-b are caused to move a greater distance than the force transfer surface 132 is caused to move by expansion of the smart material stack 110. Connected to the first stage arms 140a-b are second stage arms 150a-b. The second stage arms 150a-b may be separately formed or formed as a single structure, as shown in FIGS. 1A-B. In other words, the second stage arms 150a-b may form part of a single integrally formed spring. More specifically, as shown in FIGS. 1A-B, the two second stage arms 150a-b are part of a single bow-shaped member connecting the actuator end 142a of one first stage arm 140a to the actuator end 142b of the other first stage arm 140b. Each of the second stage arms 150a-b has an actuator end 152a-b, which is actuated by movement of the actuator end 142a-b of the first stage arms 140a-b. The actuator ends 152a-b of the second stage arms 150a-b move a greater distance than the force transfer surface 132 moves when driven by the driving end 114 of the smart material stack 110 during expansion of the smart material stack 110. Connected to the second stage arms 150a-b at the actuating ends 152a-b is an actuator surface 160. The actuator surface 160 moves a greater distance than the force transfer surface 132 moves when driven by the driving end 114 of the smart material stack 110 during expansion of the smart material stack 110.

As shown in FIGS. 1A-C, the actuator 100 includes two stages of amplification. In the first stage, the driving end 114 of the smart material stack 110 imparts axial movement to the force transfer surface 132 of the force transfer member 130. Because the first stage arms 140a-b are connected to the compensator 120, the movement of the force transfer member 130 causes the first stage arms 140a-b to rotate (e.g., pivot) relative to the compensator 120. The actuator ends 142a-b of the first stage arms 140a-b may move in an arc-shape. In the second stage of amplification, the arc-shape movement of the first stage arms 140a-b is converted into axial movement. Accordingly, both the force transfer surface 132 and the actuator surface 160 move in an axial direction. As illustrated in FIG. 1C, the force transfer surface 132 and the actuator surface 160 move in opposite directions (the dotted lines indicate the state of the actuator prior to expansion of the smart material stack 110).

Different flexibility, force and displacement characteristics of the first and second stage may be achieved by varying the length, width, and/or thickness of the first stage arms 140a-b and/or second stage arms 150a-b and/or the angle at which the second stage arms 150a-b are connected to the first stage arms 140a-b. The length and flexibility of the amplifier components can be varied to form an axial actuator having highly adjustable force and/or displacement characteristics.

Optionally, the smart material stack 110 and/or compensator 120 may be protected from environmental exposure, such as by over-molding, encapsulating, or locating the smart material stack 110 and/or compensator 120 in a housing. For example, the stack and/or compensator may be over-molded as shown in the FIGS. 1A-C. The over-molding 170, which may be, for example, ethylene propylene diene monomer (EPDM) rubber or similar material, may protect the stack from potentially harmful environmental exposure, for example, humidity, dirt and debris, etc. The over-molding 170 may also protect the stack from exposure to a working fluid. The over-molding 170 may stop before at least part of the force transfer member 130 and the links 180a-b connecting the first stage arms 140a-b to the compensator 120. In addition, onboard electronics also may be over-molded to protect them from environmental exposure (e.g., humidity, contaminants, etc.) or other potentially harmful conditions, such as high voltages.

Additionally, the actuator 100 may also include a preload mechanism 190 that is adapted to load the smart material stack 110, such as by applying force to the force transfer surface 132 in a direction opposite the direction in which the force transfer surface 132 is driven by the driving end 114 of the smart material stack 110. Various types of preloading mechanisms can be used, depending on the specific configuration of the actuator 100. FIG. 1C illustrates the actuator 100 after preload (dotted lines) and after actuation (solid lines) resulting from expansion of the smart material stack 110.

One or more of the elements of the actuator 100 may be formed by metal injection molding (also referred to as “MIM”). For example, the compensator 120, the force transfer member 130, the first stage arms 140a-b, and/or the second stage arms 150a-b may be formed by MIM processes. In addition, the compensator 120 may be suitable to manufacture using a stamping process, or any other suitable manufacturing process, depending on its size and shape. As illustrated, the compensator 120 and the first stage arms 140a-b are separately formed and connected together. If separately (as opposed to integrally) formed, the compensator and the first stage arms 140a-b may be connected together using any suitable connection mechanism, such as the puzzle locks 122. Accordingly, the compensator 120 and first stage arms 140a-b may be manufactured from different materials without the cost and complexity associated with MIM two different materials to form the compensator 120 and first stage arms 140a-b as a single part. In addition, the various elements of the actuator 100 may be made from any suitable materials, including but not limited to Invar, steel, spring steel, aluminum, and the like.

One or more of the elements of the actuator 100 may be formed from spring steel. For example, the second stage arms 150a-b, the link 180 are formed of spring steel, for example, by a spring maker. The second stage arms 150a-b, if not integrally formed with the first stage arms, may be connected to the first stage arms 140a-b using any known connection mechanism. For example, the first stage arms 140a-b may have holes adapted to receive the ends of the second stage arms 150a-b. The connection between the first stage arms 140a-b and the second stage arms 150a-b may be secured by adhesive or an interference fit between the ends of the second stage arms 150a-b and the holes may be achieved by requiring the second stage arms 150a-b to be preloaded to fit in the holes in the first stage arms 140a-b.

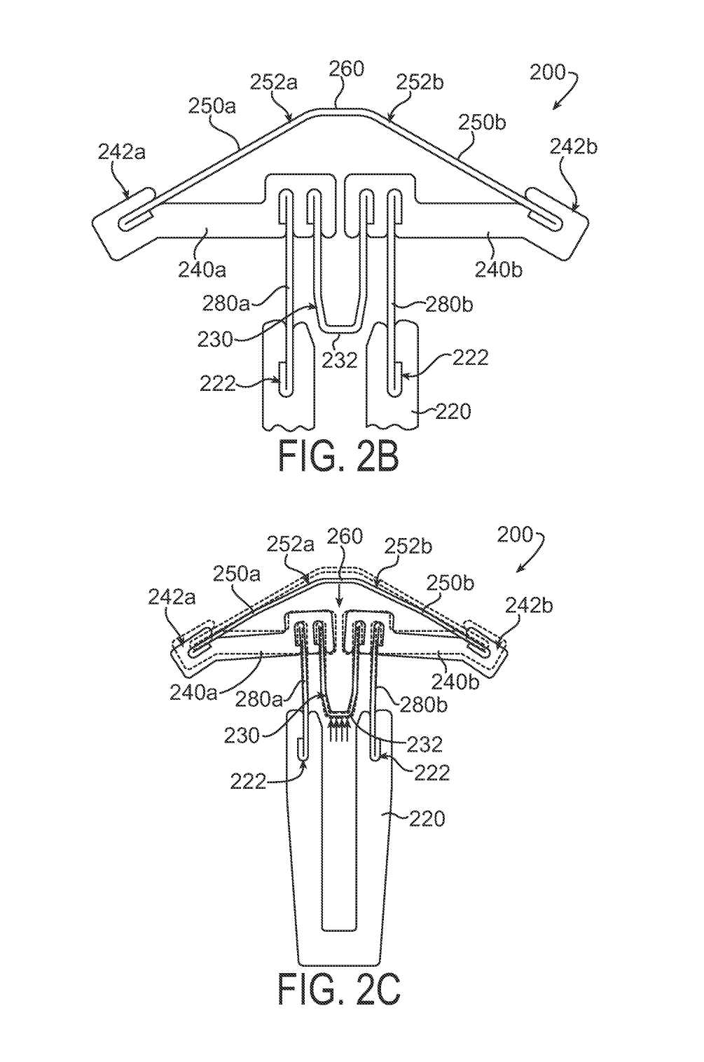

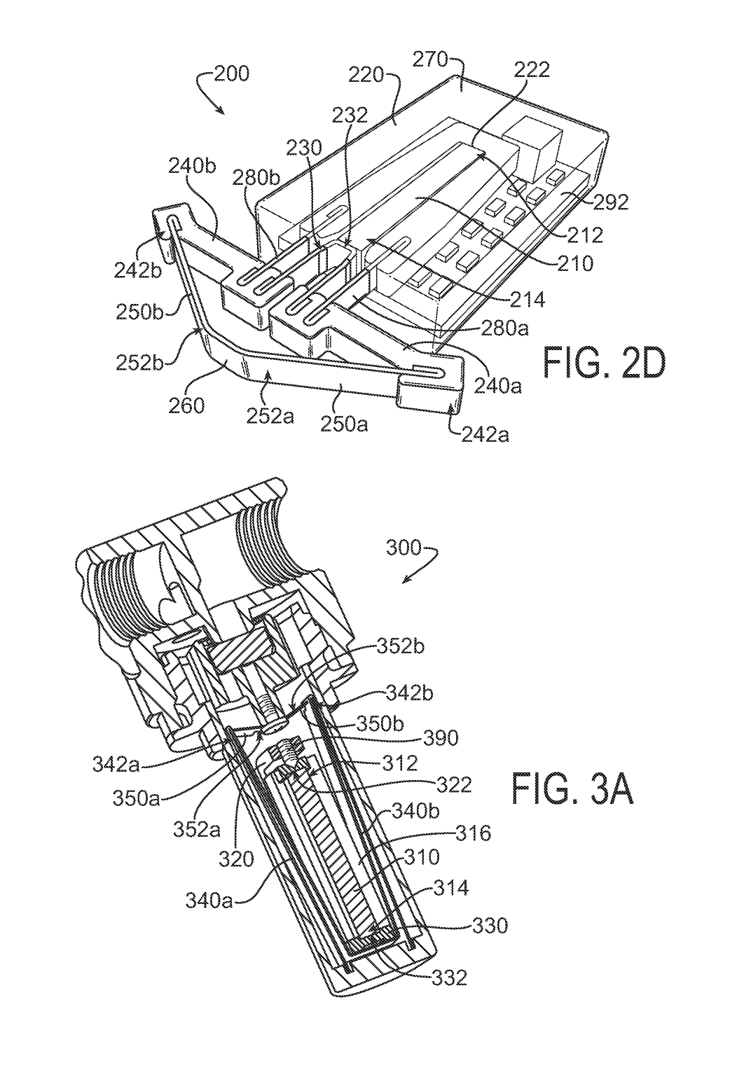

Turning next to FIGS. 2A-D, the actuator 200 is similar in function and design to the actuator 100 of FIGS. 1A-B, but may be made using different materials and manufacturing processes. Like the actuator 100, the actuator 200 includes two stages of amplification. In the first stage, the driving end 214 of the smart material stack 210 imparts axial movement to the force transfer surface 232 of the force transfer member 230. Because the first stage arms 240a-b are connected to the compensator 220, the movement of the force transfer member 230 causes the first stage arms 240a-b to rotate (e.g., pivot) relative to the compensator 220. The actuator ends 242a-b of the first stage arms 240a-b may move in an arc-shape. In the second stage of amplification, the arc-shape movement of the first stage arms 240a-b is converted into axial movement. Accordingly, both the force transfer surface 232 and the actuator surface 260 move in an axial direction. As illustrated in FIG. 2C, the force transfer surface 232 and the actuator surface 260 move in opposite directions (the dotted lines indicate the state of the actuator prior to expansion of the smart material stack 210).

Also like the actuator 100, the smart material stack 210 and/or compensator 220 may be protected from environmental exposure, such as by over-molding, encapsulating, or locating the smart material stack 210 and/or compensator 220 in a housing. For example, the stack and/or compensator may be over-molded as shown in the FIGS. 2A-C. The over-molding 270, which may be, for example, EPDM rubber or similar material, may protect the stack from potentially harmful environmental exposure, for example, humidity, dirt and debris, etc. The over-molding 270 may also protect the stack from exposure to a working fluid. The over-molding 270 may stop before at least part of the force transfer member 230 and the links 280a-b connecting the first stage arms 240a-b to the compensator 220. In addition, onboard electronics also may be over-molded to protect them from environmental exposure (e.g., humidity, contaminants, etc.) or other potentially harmful conditions, such as high voltages. In addition, FIG. 2D illustrates an example of how electronic circuitry 292 may be over-molded in addition to the smart material stack 210 and/or compensator 220. The electronic circuitry may include hardware and/or software for controlling the application of electrical energy to the smart material stack 210.

As shown in FIGS. 2A-D, each of the first stage arms 240a-b, the force transfer member 230, the compensator 220 and the links 280a-b connecting the first stage arms 240a-b to the compensator 220 may be formed separately. Accordingly, the various elements of the actuator 200 may each be formed from different suitable materials, such as Invar, steel, spring steel, aluminum, and the like. For example, the actuator 200 an Invar compensator 220, spring steel links 280a-b and force transfer member 230, extruded aluminum first stage arms 240a-b, and spring steel second stage arms 250a-b. As shown, these components may be loosely assembled and pushed or pulled into place with respect to one another. Preloading the first stage arms 240a-b and/or second stage arms 250a-b may lock the elements in place without requiring further operations such as staking, gluing or brazing. As will be understood by those of skill in the art, the use of discrete components may decrease manufacturing costs by allowing the various components to be made from different materials using potentially less expensive manufacturing processes.

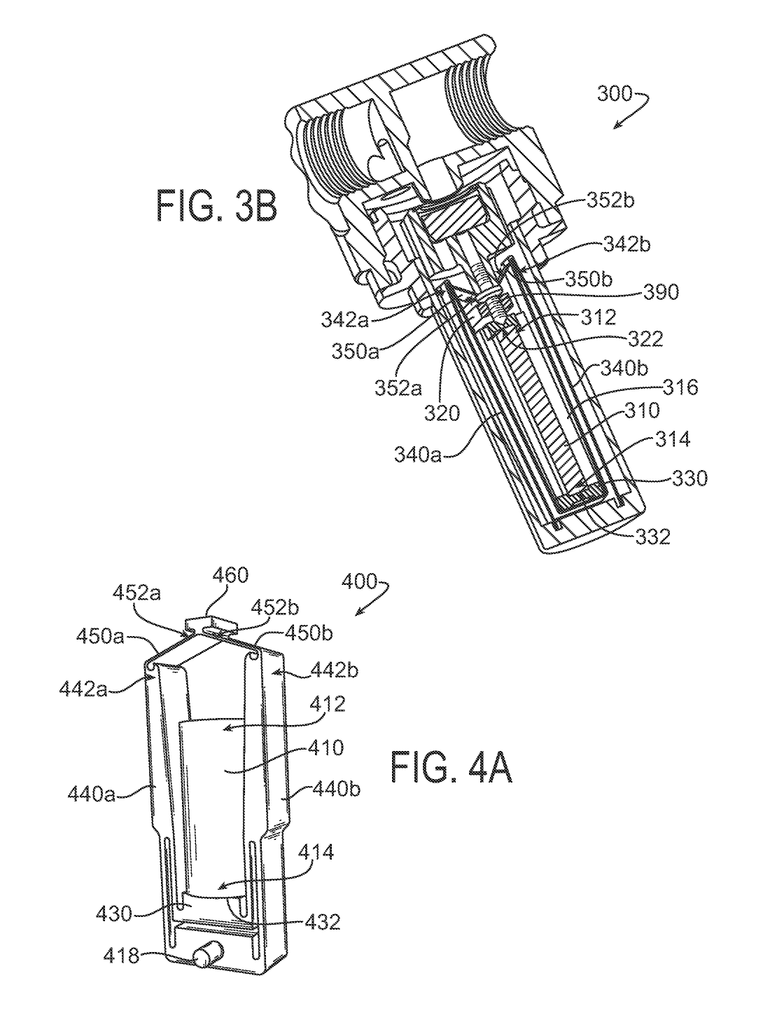

Turning next to FIGS. 3A-B, an actuator 300 suitable for housing within a cylinder is disclosed. FIG. 3A shows the actuator 300 in an open position and FIG. 3B shows the actuator 300 in a closed position. Like the actuator 100, the actuator 300 includes a smart material stack 310 that is at least partially contained within a compensator 320. The stack 310 has a fixed end 312 and a driving end 314. In addition the smart material stack 310 may be potted, such as by the over molding 316 of the smart material stack 310. The compensator 320 includes a fixed surface 322 adjacent to, or abutting, the fixed end 312 of the smart material stack 310. Adjacent the driving end 314 of the smart material stack 310 is a force transfer surface 332, which may be located on a force transfer member, such as force transfer member 330.

The force transfer member 330 is adjacent the upwardly extending first stage arms 340a and 340b, which are part of a first stage amplifier. The first stage arms 340a and 340b each have an actuator end, 342a and 342b, respectively. Exposure of the smart material stack 310 to electrical energy may cause the smart material stack 310 to expand axially, thereby causing the driving end 314 of the smart material stack 310 to move the force transfer surface 332, which in turn causes movement of the actuator ends 342a-b of the first stage arms 340a-b. As shown, the first stage arms 340a-b are folded spring arms that are formed as a single structure, such as from spring steel, in which movement of the force transfer surface 332 causes force to be exerted between arms 340a and 340b. In this way, the force transfer surface 332 is part of a force transfer member 330 that actuates the two first stage arms 340a-b via interaction with a single link between the first stage arms 340a-b. Because the arms 340a-b are connected (e.g., integrally formed), the actuator ends 342a-b, which are opposite the force transfer surface 332, are caused to move closer to one another.

In addition, as shown in FIGS. 3A-B, the compensator 320 may be generally U-shaped and may be 90 degrees offset from the first stage arms 340a-b. In other words, the first stage arms 340a-b may extend outwardly from the smart material stack 310 in a first direction while the compensator 320 extends outwardly from the smart material stack 310 in a direction offset from the first stage arms 340a-b by approximately 90 degrees. Having the first stage arms 340a-b and the compensator 320 offset by 90 degrees may make the actuator more suitable for use in a solenoid housing.

The first stage arms 340a-b may amplify the movement of the force transfer surface 332 such that the actuator ends 342a-b of the first stage arms 340a-b are caused to move a greater distance than the force transfer surface 332 is caused to move by expansion of the smart material stack 310. Connected to the first stage arms 340a-b are second stage arms 350a-b. The second stage arms 350a-b may be separately formed as shown in FIGS. 3A-B or formed as a single structure. Each of the second stage arms 350a-b has an actuator end 352a-b, which is actuated by movement of the actuator end 342a-b of the first stage arms 340a-b. The actuator ends 352a-b of the second stage arms 350a-b move a greater distance than the force transfer surface 332 moves when driven by the driving end 314 of the smart material stack 310 during expansion of the smart material stack 310. Connected to the second stage arms 350a-b at the actuating ends 352a-b is a valve pin, which also may be a screw or the like, the movement of which actuates a mechanism for opening and closing a fluid pathway.

Also like the actuator 100, the actuator 300 includes two stages of amplification. In the first stage, the driving end 314 of the smart material stack 310 imparts axial movement to the force transfer surface 332 of the force transfer member 330. The downward movement of the force transfer surface 332 causes the first stage arms 340a-b to rotate (e.g., pivot) relative to the force transfer surface 332. The actuator ends 342a-b of the first stage arms 340a-b may move in an arc-shape. In the second stage of amplification, the arc-shape movement of the first stage arms 340a-b is converted into axial movement. Accordingly, both the force transfer surface 332 and the valve pin move in an axial direction. As illustrated in FIGS. 3A-B, the force transfer surface 332 and the valve pin move in the same direction when the smart material stack 310 is actuated.

Additionally, the actuator 300 may also include a preload mechanism 390 that is adapted to load the smart material stack 310, such as by applying force to the fixed surface 322 of the compensator 320 in the same direction in which the force transfer surface 332 is driven by the driving end 314 of the smart material stack 310.

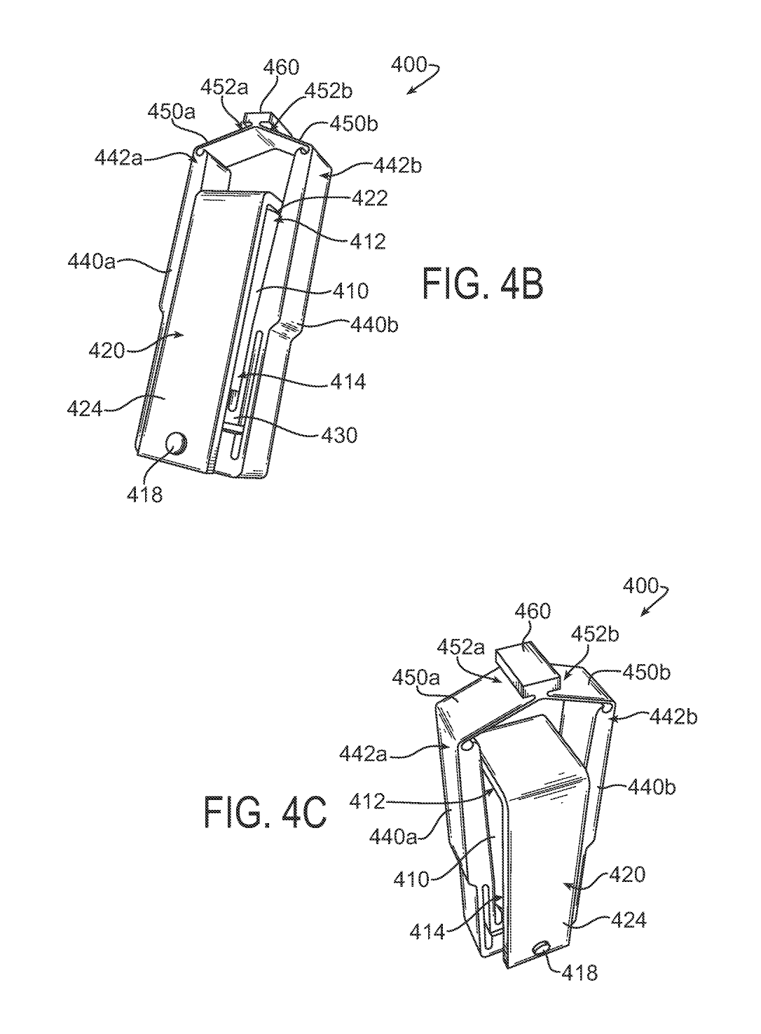

Turning next to FIGS. 4A-B, an actuator 400 suitable for housing within a cylinder is disclosed. Like the actuator 300, the actuator 400 includes a smart material stack 410 that is at least partially contained within a compensator 420. The stack 410 has a fixed end 412 and a driving end 414. In addition the smart material stack 410 may be potted, such as by the over molding of the smart material stack 410. The compensator 420 includes a fixed surface 422 adjacent to, or abutting, the fixed end 412 of the smart material stack 410. Adjacent the driving end 414 of the smart material stack 410 is a force transfer surface 432, which may be located on a force transfer member, such as force transfer member 430.

The force transfer member 430 is adjacent the upwardly extending first stage arms 440a and 440b, which are part of a first stage amplifier. The first stage arms 440a and 440b each have an actuator end, 442a and 442b, respectively. Exposure of the smart material stack 410 to electrical energy may cause the smart material stack 410 to expand axially, thereby causing the driving end 414 of the smart material stack 410 to move the force transfer surface 432, which in turn causes movement of the actuator ends 442a-b of the first stage arms 440a-b. As shown, the first stage arms 440a-b integrally formed with the force transfer member 430 and force transfer surface 432, which is located between the arms 440a and 440b. Accordingly, the actuator ends 442a-b, which are opposite the force transfer surface 432, are caused to move closer to one another when the force transfer surface 432 is driven downward.

Like the actuator 300, the actuator 400 has a compensator 420 that is 90 degrees offset from the first stage arms 440a-b. In other words, the first stage arms 440a-b extend outwardly from the smart material stack 410 in a first direction while the compensator 420 extends outwardly from the smart material stack 410 in a direction offset from the first stage arms 440a-b by approximately 90 degrees. Having the first stage arms 340a-b and the compensator 320 offset by 90 degrees may make the actuator more suitable for use in a solenoid housing.

The compensator 420 may be generally U-shaped and fixed to the base of the actuator 400, or to the base of a housing for the actuator, using any type of connection mechanism, such as bolt 418. The manner and location of fixation of the compensator 420 may be modified, so long as the compensator 420 has a fixed surface 422 adjacent the fixed end 412 of the smart material stack 410 that prevents expansion of the smart material stack.

As shown in FIGS. 4A-C, the force transfer member 430, force transfer surface 432, first stage arms 440a-b, second stage arms 450a-b and actuation surface 460 are all integrally formed, and may be formed by MIM or any other suitable process. The compensator 420, which is a separate element, may be stamped or manufactured using any other suitable process. The first stage arms 440a-b may amplify the movement of the force transfer surface 432 such that the actuator ends 442a-b of the first stage arms 440a-b are caused to move a greater distance than the force transfer surface 432 is caused to move by expansion of the smart material stack 410. Each of the second stage arms 450a-b has an actuator end 452a-b, which is actuated by movement of the actuator end 442a-b of the first stage arms 440a-b. The actuator ends 452a-b of the second stage arms 450a-b move a greater distance than the force transfer surface 332 moves when driven by the driving end 314 of the smart material stack 310 during expansion of the smart material stack 310. Connected to (e.g., integrally formed with) the second stage arms 450a-b at the actuating ends 452a-b is an actuator surface 460. The actuator surface 460 moves a greater distance than the force transfer surface 432 moves when driven by the driving end 414 of the smart material stack 410 during expansion of the smart material stack 410.

Also like the actuator 300, the actuator 400 includes two stages of amplification. In the first stage, the driving end 414 of the smart material stack 410 imparts axial movement to the force transfer surface 432 of the force transfer member 430. The downward movement of the force transfer surface 432 causes the first stage arms 440a-b to rotate (e.g., pivot) relative to the force transfer surface 432. The actuator ends 442a-b of the first stage arms 440a-b may move in an arc-shape. In the second stage of amplification, the arc-shape movement of the first stage arms 440a-b is converted into axial movement. Accordingly, both the force transfer surface 332 and the actuator surface 460 move in an axial direction. As illustrated in FIGS. 3A-B, the force transfer surface 432 and the actuator surface 460 move in opposite directions when the smart material stack 410 is actuated.

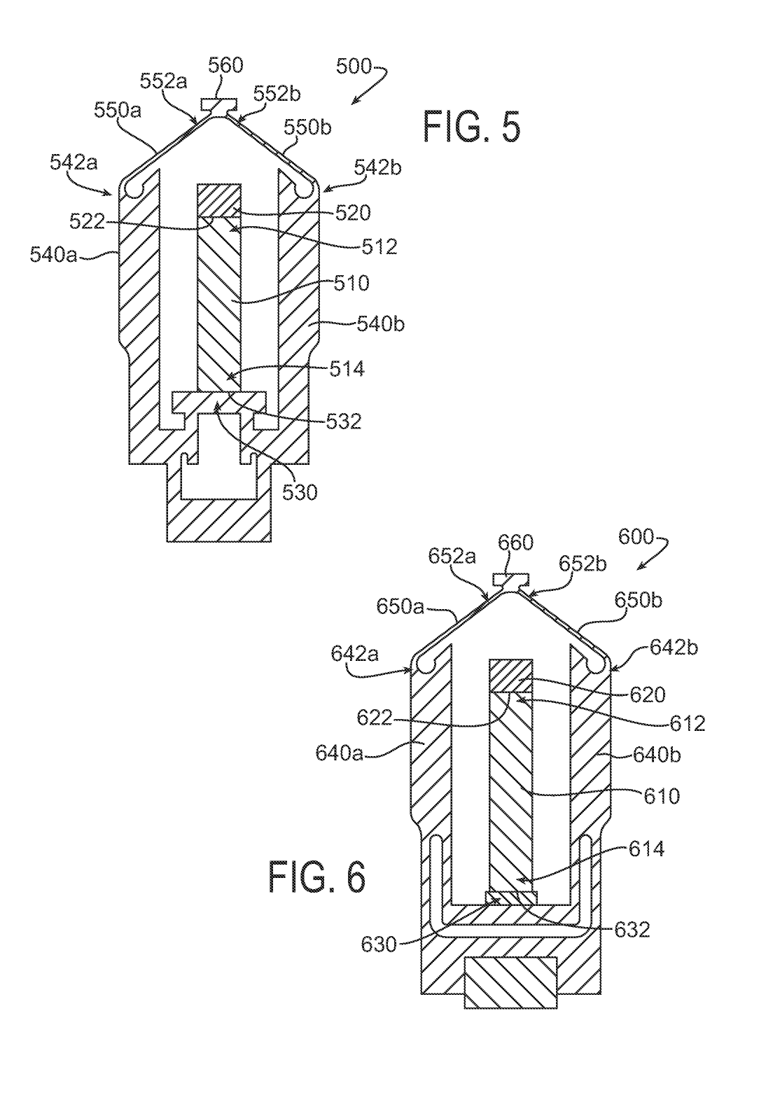

Turning next to FIGS. 5-7, different variations of the embodiment disclosed in FIGS. 4A-C are illustrated. Similar components are numbered similarly (e.g., smart material stack x10, compensator x20, force transfer member x30, first stage arms x40, second stage arms x50, etc., where “x” is the Figure number) and have similar functionality.

Other embodiments in which the smart material stack x10 is protected from environmental factors by a housing are illustrated in FIGS. 8-10. Each of the actuators x00 includes a smart material stack x10 that is located within a housing x72 (e.g., a can), which may be a force transfer member x30 having a force transfer surface x32. For example, as shown in FIG. 8, the bottom portion of the housing x72 may engage the first stage arms x40a-b, such as with a flange. The stack x10 has a fixed end x12 and a driving end x14. The compensator x20 includes a fixed surface x22 adjacent to, or abutting, the fixed end x12 of the smart material stack x10. Adjacent the driving end x14 of the smart material stack x10 is a force transfer surface x32, which may be located on a force transfer member, such as force transfer member x30. One or more o-ring seals x74 may be provided to form a sealed compartment in which the smart material stack x10 is located. In addition, another o-ring seal x74 may be used in conjunction with a preload mechanism x90, such as threads. The use of o-rings may eliminate the need to weld the housing x72 shut for humidity protection while still permitting movement of the housing x72 caused by expansion of the smart material stack x10. In addition, elimination of welding requirements may have additional manufacturing benefits, such as providing additional component flexibility, as will be understood by those skilled in the art.

In the configurations illustrated in FIGS. 8-10, the when the smart material stack x10 is energized, it forces the entire housing x72 to move upwards away from the base of the actuator. The movement of the housing x72 may cause rotation (e.g., rolling) of the o-ring seal x74. Preferably, however, the smart material stack x10 remains sealed within the housing x72, limiting exposure to the environment.

Also, as shown in FIG. 10, the actuators may include a biasing element, such as spring 1092, to bias a second stage amplifier including second stage arms x50a-b.

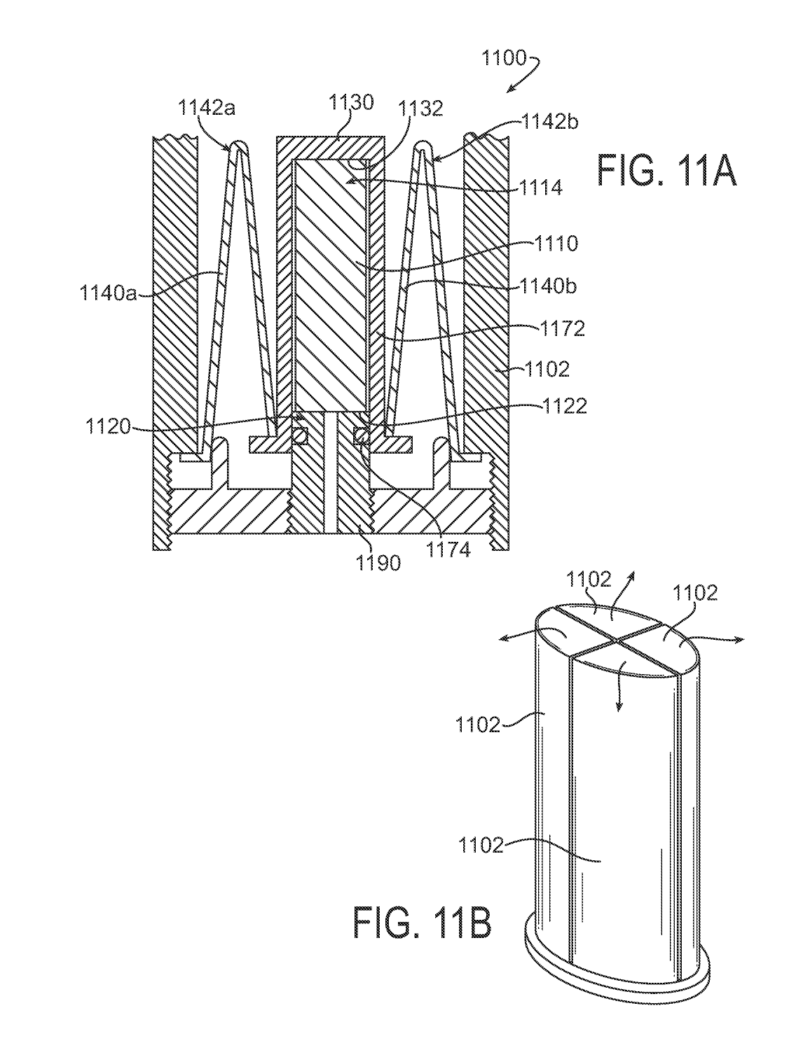

Turning next to FIGS. 11A-16, the smart material actuator may be used in a split can amplifier, such as that illustrated in 11B, having, for example, four or more arms that move inwardly or outwardly to provide a clamping action when the smart material stack x10 is energized. For example, the amplifier may include a can that is split down its length in an “X” shape (or another shape) so that the amplifier has four arms x02 (or more/less depending on the shape in which the amplifier is split) that spread open when forces are applied to the base. In the split can embodiments, movement of the force transfer surface x32 may causes the two first stage arms x40a-b to move radially outward.

In addition to the features described above with respect to FIGS. 1-10, the actuators of FIGS. 11-16 may include first stage arms x40a-b that are connected to the base in a variety of different ways, including, for example, a rivet or other mechanical connector, or by an interference fit achieved by preloading the smart material stack x10. Additionally, the spring arms may be separate components from one another, connected by a rivet or other mechanical connector.

The actuators in the split can amplifier may also include a second stage of amplification, including second stage arms x50a-b. The split can amplifier also may include a second stage of amplification to convert the rotational movement of the arms into axial movement. Although shown as having four arms, the split can may be configured to have more or fewer arms as may be desired.

Turning next to FIGS. 17-25, different shapes and configurations of actuators are illustrated.

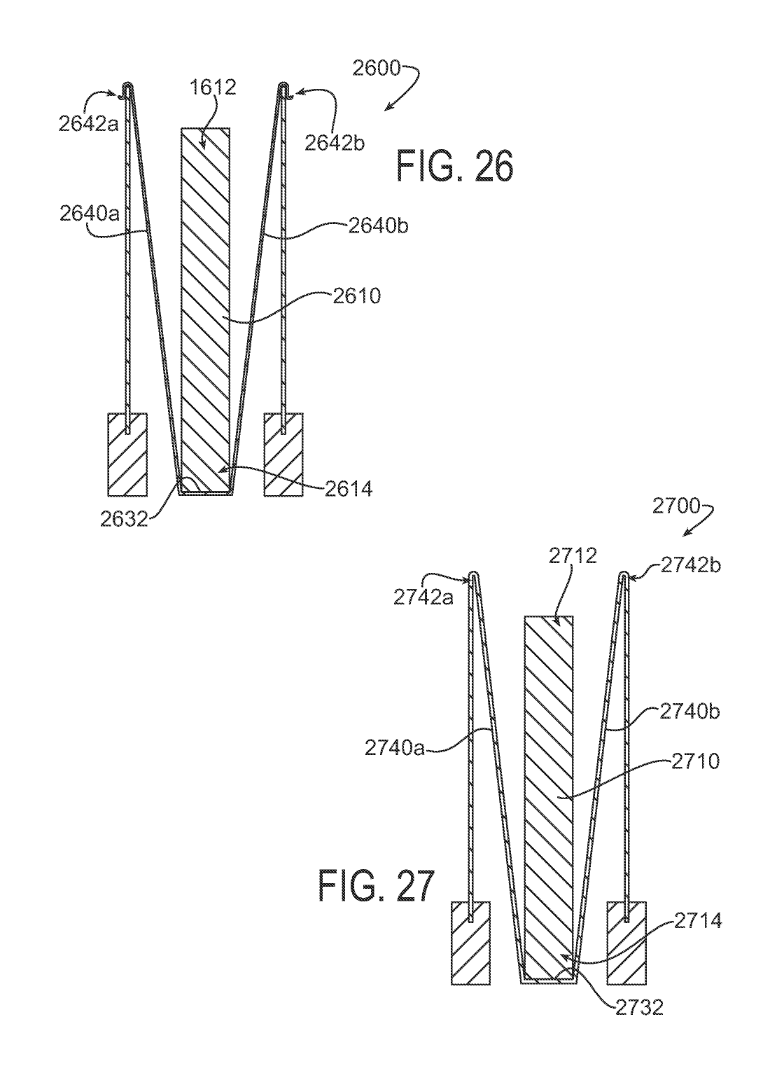

Turning next to FIGS. 26-33, different shapes and types of first stage arms x40a-b and second stage arms x50a-b are illustrated.

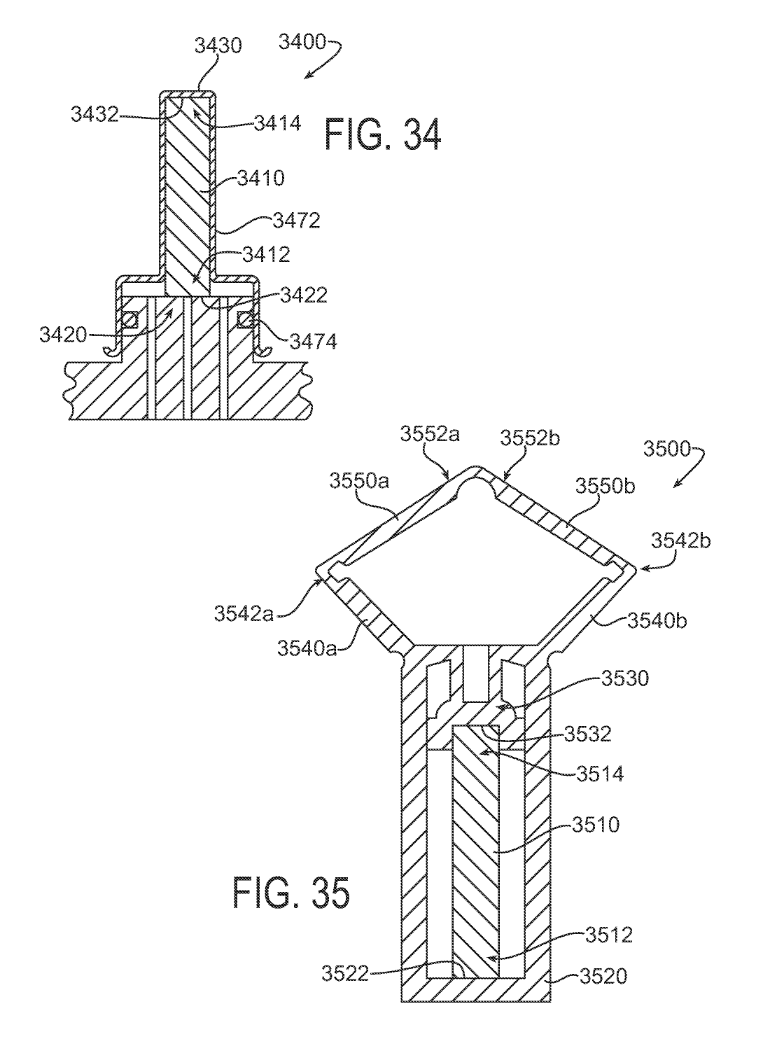

Turning next to FIG. 34, an actuator with a different type of housing x72 is illustrated.

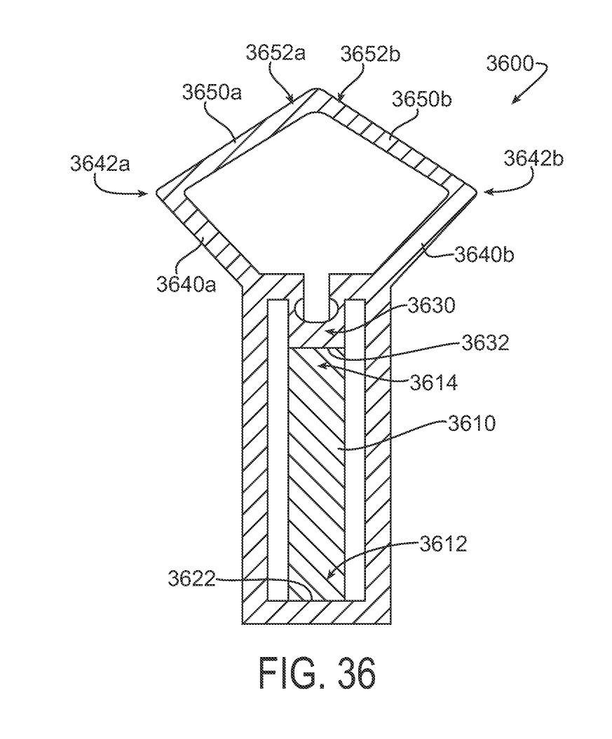

Turning next to FIGS. 35-36, actuators particularly suitable for manufacture by stamping are illustrated. The compensator x20, force transfer member x30, first stage arms x40, second stage arms and x50 may be integrally formed by stamping. In addition, the actuator ends x42a-b of the first stage arms and the actuator ends x52 of the second stage arms x50 may be etched or formed by electrical discharge machining or another process.

Those skilled in the art will understand that the many of the embodiments described herein include discrete elements (e.g., compensator x20, force transfer member x30, first stage arms x40a-b and second stage arms x50a-b). Using separate elements increases manufacturing options and flexibility, which may be leveraged to decrease manufacturing costs. Any suitable manufacturing process may be used for the elements described here. It should be understood that while MIM, stamping, extrusion, and etching of components are discussed, other types of manufacturing processes may be used and that the invention is not to be limited to any particular type of manufacturing process.

It will be understood by those of skill in the art that the actuators described herein can be used with both normally open and normally closed systems. One of skill in the art should understand that a normally open system using an actuator described herein can be converted to a normally closed system by modifying the configuration of spring elements to reverse the bias of the actuator.

Although the actuators illustrated in many of the figures are symmetric it should be understood by those skilled in the art that the actuators may be asymmetric.

Although the principles, embodiments and operation of the present invention have been described in detail herein, this is not to be construed as being limited to the particular illustrative forms disclosed. They will thus become apparent to those skilled in the art that various modifications of the embodiments herein can be made without departing from the spirit or scope of the invention.

1. A smart material actuator comprising:
a smart material stack having a fixed end and a driving end;
a compensator at least partially surrounding the smart material stack and providing a fixed surface adjacent the fixed end of the smart material stack;
a force transfer surface adjacent the driving end of the smart material stack, wherein the force transfer surface is driven by the driving end of the smart material stack; and
an amplifier comprising:
two first stage arms having an actuator end and being actuated by movement of the force transfer surface, and
two second stage arms having an actuator end and being actuated by movement of the actuator end of the first stage arms, wherein movement of the actuator end of the first stage arms causes the actuator end of the second stage arms to move a greater distance than the force transfer surface is driven by the driving end of the smart material stack,
wherein the first stage arms extend outwardly from the smart material stack in a first direction and the compensator extends outwardly from the smart material stack in a direction offset from the first stage arms by approximately 90 degrees.

2. A smart material actuator comprising:
a smart material stack having a fixed end and a driving end;
a generally U-shaped compensator at least partially surrounding the smart material stack and providing a fixed surface adjacent the fixed end of the smart material stack;
a force transfer member having a force transfer surface adjacent the driving end of the smart material stack, wherein the force transfer surface is driven by the driving end of the smart material stack; and
two first stage arms having an actuator end and being actuated by movement of the force transfer member, wherein the two first stage arms are offset by 90 degrees from the sides of the U-shaped compensator;
wherein actuation of the smart material stack drives movement of the force transfer member, which causes the actuator end of the first stage arms to move a greater distance than the force transfer surface is driven by the driving end of the smart material stack.

3. The smart material actuator of claim 2, further comprising two second stage arms having an actuator end, which is actuated by movement of the actuator end of the first stage arms, wherein the actuator end of the second stage arms move a greater distance than the force transfer surface moves when driven by the driving end of the smart material stack.

4. The smart material actuator of claim 1, further comprising an actuator surface driven by the actuator ends of the second stage arms, wherein the movement of the actuator surface is greater than the movement of the force transfer surface when driven by the driving end of the smart material stack.

5. The smart material actuator of claim 4, wherein the actuator surface and the force transfer surface move in an axial direction.

6. The smart material actuator of claim 4, wherein movement of the force transfer surface causes the actuator surface to move a direction generally opposite that of the movement of the force transfer surface.

7. The smart material actuator of claim 1, wherein the smart material stack is at least one of: over-molded; encapsulated; or located within a housing.

8. The smart material actuator of claim 7, further comprising an o-ring seal in contact with the housing to limit environmental exposure of the smart material stack.

9. The smart material actuator of claim 8, wherein movement of the housing as a result of actuation of the smart material stack causes rolling of the o-ring seal.

10. The smart material actuator of claim 1, further comprising at least one link connecting the compensator to each of the two first stage arms.

11. The smart material actuator of claim 10, wherein the at least one link is formed from spring steel.

12. The smart material actuator of claim 1, wherein the force transfer surface is part of a force transfer member that actuates the two first stage arms via interaction with a single link between the first stage arms.

13. The smart material actuator of claim 1, wherein the two first stage arms are folded spring arms.

14. The smart material actuator if claim 1, wherein at least one of the two first stage arms or the compensator is metal injection molded.

15. The smart material actuator of claim 1, wherein the compensator and the two first stage arms are formed by different manufacturing processes.

16. The smart material actuator of claim 1, wherein at least one of the two first stage arms, or the two second stage arms is formed from spring steel.

17. The smart material actuator of claim 1, wherein the two first stage arms are part of a single integrally formed spring or the two second stage arms form part of a single integrally formed spring.

18. The smart material actuator of claim 1, wherein the two second stage arms are part of a bow-shaped member connecting the actuator end of one of the first stage arms to the actuator end of the other of the first stage arms.

19. The smart material actuator of claim 1, wherein the two first stage arms are part of a split can amplifier, and wherein movement of the force transfer surface causes the two first stage arms to move radially outward.

20. The smart material actuator of claim 1, further comprising a preload mechanism adapted to apply force to the force transfer surface in a direction opposite the direction in which the force transfer surface is driven by the driving end of the smart material stack.
